(19) United States
(12) Patent Application Publication
(10) Pub. No.: US 2013/0221421 A1
(43) Pub. Date: Aug. 29, 2013

(54) STACKED-GATE NON-VOLATILE FLASH MEMORY CELL, MEMORY DEVICE AND MANUFACTURING METHOD THEREOF

(71) Applicants: Jianhong Mao, Shanghai (CN); Fengqin Han, Shanghai (CN)

(72) Inventors: Jianhong Mao, Shanghai (CN); Fengqin Han, Shanghai (CN)

(73) Assignee: LEXVU OPTO MICROELECTRONICS TECHNOLOGY (SHANGHAI) LTD, Shanghai (CN)

(21) Appl. No.: 13/637,022

(22) PCT Filed: Jan. 26, 2011
(86) PCT No.: PCT/CN11/70634

§ 371 Date: May 20, 2013

(30) Foreign Application Priority Data
Mar. 25, 2010 (CN) 201010135700.3

(51) Int. Cl. H01L 29/788; H01L 29/66

(52) U.S. Cl. CPC H01L 29/788; H01L 29/66825
USPC 257/315; 438/257

(57) ABSTRACT

A stacked-gate non-volatile flash memory cell, a memory device including the memory cell, and a manufacturing method thereof are provided. The memory cell includes a semiconductor structure and a movable switch (200), wherein the semiconductor structure includes an extended floating gate structure, and an interlayer dielectric layer (114) with an opening (1204) through which the extended floating gate structure is exposed; meanwhile, the movable switch (200) includes a support component (210) and a conductive interconnection component (220), the support component (210) is located on the periphery of the conductive interconnection component and connected with the interlayer dielectric layer, and the conductive interconnection component is floating over the opening. When a voltage is applied to the conductive interconnection component, the conductive interconnection component is electrically connected with the extended floating gate structure, so that the advantages of simple control circuit, low manufacturing cost, high reliability, low power consumption and high efficiency are obtained.

### CROSS REFERENCE TO RELATED APPLICATIONS

The present application claims priority to Chinese Patent Application No. 201010135700.3, filed on Mar. 25, 2010, and entitled “STACKED-GATE NON-VOLATILE FLASH MEMORY CELL, MEMORY DEVICE AND MENUFACTURING METHOD THEREOF”, the entire disclosure of which is incorporated herein by reference.

### FIELD OF THE DISCLOSURE

The present disclosure relates to semiconductor memory devices, and more particularly, to a stacked-gate non-volatile flash memory cell, a memory device and a manufacturing method thereof

### BACKGROUND OF THE DISCLOSURE

Normally, semiconductor memory devices adapted for data storage includes two kinds, volatile memory devices and non-volatile memory devices. Volatile memory devices lose their stored data when power off, but non-volatile memory devices maintain data even after power off. Currently there are several types of non-volatile memory devices, such as electrically programmable read-only-memory (EPROM) devices, electrically erasable programmable read-only-memory (EEPROM) devices and flash memory devices. Compared with other non-volatile memory devices, flash memory devices feature the advantage of non-volatility, low power consumption, electrically rewritable capability and low cost. Therefore, non-volatile memory devices are widely used in various fields including embedded systems such as personal computers, PC peripheral equipment, telecom switches, cellular phones, network interconnection devices, instruments and vehicle devices. Non-volatile memory devices can also be utilized in novel products relating to voice, image or data storage, such as digital cameras, digital voice recorders and personal digital assistants.

FIG. 1 illustrates a schematic cross-sectional view of a conventional stacked-gate memory cell. As shown in FIG. 1, the memory cell includes a substrate 10, a doped well region 20 in the substrate 10 and a stacked-gate transistor disposed in and on the doped well region. The stacked-gate transistor includes a source region 30S, a drain region 30D, a floating gate structure 30G which is disposed on the substrate 10 between the source region 30S and the drain region 30D, an isolating layer 40 overlaying the floating gate structure 30G, and a controlling gate structure 50 on the isolating layer 40. The floating gate structure 30G includes a gate oxide layer 301 and a polysilicon layer 302 on the gate oxide layer 301, and further includes an insulating layer 303 on the polysilicon layer 302. For example, a memory cell is disclosed in Chinese Patent Publication No. CN 101320735A.

In a conventional write operation performed to the stacked-gate memory cell, a positive voltage of +5 V is applied to the source region 30S, a relatively low voltage which is grounded is applied to the drain region 30D and another relatively low voltage which is grounded is applied to the controlling gate structure 50. Due to a conductive channel formed between the source region 30S and the drain region 30D, the voltage of +5 V is transferred from the source region 30S to the drain region 30D through the conductive channel. In the conductive channel, holes or electrons may be implanted into the floating gate structure 30G as a result of the hot carrier effect, thereby accomplishing the write operation.

Conventionally, an erase operation is performed under mechanism of hot electron tunneling or electron tunneling, in which a high operating voltage is necessarily performed to the controlling gate structure 50, for example, from about 7 V to about 20 V. Therefore, high-voltage devices are necessarily involved in the non-volatile memory devices, resulting in a complicated manufacturing process and higher costs. Besides, repeated erase operations with the hot electron tunneling or electron tunneling may lead to the transistor failure. Therefore, the conventional stacked-gate non-volatile flash memory cells may not have desired reliability.

### BRIEF SUMMARY OF THE DISCLOSURE

Embodiments of the present disclosure provide a stacked-gate non-volatile flash memory cell and a manufacturing method thereof, to improve the reliability of the memory cell.

To achieve the objection, one embodiment of the present disclosure provides a stacked-gate non-volatile flash memory cell. The memory cell includes a semiconductor structure which includes a substrate, a doped well in the substrate, a stacked-gate transistor in and on the doped well. The stacked-gate transistor includes a source region, a drain region, a floating gate structure disposed between the source and the drain, an isolating layer which covers the floating gate structure and a controlling gate structure disposed on the isolating. The semiconductor structure further includes an extended floating gate structure which is an extended structure of the floating gate structure on the substrate, and an interlayer dielectric (ILD) layer is disposed on the semiconductor structure.

The memory cell further includes a movable switch disposed above the floating gate structure. An opening corresponding to the movable switch and exposing the extended floating gate structure is disposed in the ILD layer. The movable switch includes: a support component and a conductive interconnection component. One end of the support component connects to the border of the conductive interconnection component, another end of the support component connects to the ILD layer, so that the conductive interconnection component suspends above the opening. The conductive interconnection component electrically connects to the extended floating gate structure when a voltage is applied to the conductive interconnection component.

Optionally, the isolating layer covers the extended floating gate structure, and there is an opening in the isolating layer, the opening in the isolating layer corresponds to the opening in the ILD layer.

Optionally, the doped well is N type and the stacked-gate transistor is a PMOS transistor.

Optionally, the doped well is P type and the stacked-gate transistor is a NMOS transistor.

Optionally, the support component includes insulating material, and the support component is configured as pins distributed on two symmetrical opposite sides of the conductive interconnection component. The one end the support component connecting to the conductive interconnection component is disposed under the conductive interconnection component, and the another end of the support component connecting to the ILD layer is disposed on the ILD layer.

Optionally, the extended floating gate structure includes a polysilicon layer and an insulating layer on the polysilicon layer. The opening includes a first portion in the ILD layer and a second portion which is in the insulating layer and corresponds to the first portion's central region, and the opening's second portion corresponds to the first portion's central region.

Optionally, the conductive interconnection component includes a convex portion towards the extended floating gate structure, and the convex portion corresponds to the opening's second portion in the insulating layer.

Optionally, the conductive interconnection component corresponds to the opening's central region.

Optionally, the conductive interconnection component includes metal.

A stacked-gate non-volatile flash memory device including an array of above mentioned stacked-gate non-volatile flash memory cells is provided according to another embodiment.

Another embodiment provides a method for forming a stacked-gate non-volatile flash memory cell, including:

Providing a semiconductor structure, wherein the semiconductor structure includes a substrate, a doped well in the substrate, a stacked-gate transistor in and on the doped well, wherein the stacked-gate transistor includes a source region, a drain region, a floating gate structure disposed between the source and the drain, an isolating layer which covers the floating gate structure and a controlling gate structure disposed on the isolating, the semiconductor structure further includes an extended floating gate structure which is an extended structure of the floating gate structure on the substrate, and an interlayer dielectric (ILD) layer is disposed on the semiconductor structure;

Etching the semiconductor structure to form a first opening in the ILD layer on the extended floating gate structure;

Forming a sacrificial layer to fill the first opening;

Forming a barrier layer on the ILD layer, the barrier layer covering portions of the sacrificial layer;

Etching the barrier layer to form a second opening in the barrier layer, the second opening exposing the sacrificial layer;

Forming a conductive layer on the barrier layer, the conductive layer covering the second opening; and

Removing the sacrificial layer in the first opening.

Optionally, the isolating layer covers the extended floating gate structure, the extended floating gate structure includes a polysilicon layer and an insulating layer disposed on the polysilicon layer, and the step for etching the extended semiconductor structure to form a first opening includes:

Etching the ILD layer and the isolating layer to form a first portion of the first opening; and

Etching the insulating layer exposed by the first opening's first portion to form the first opening's second portion in the insulating layer.

Optionally, the barrier layer corresponds to the first opening's central region, and the second opening corresponds to the first opening's central region.

Optionally, the insulating layer includes silicon nitride.

Optionally, the conductive layer includes metal.

Compared with the prior art, embodiments of the present disclosure have advantageous below:

A moveable switch is configured above the extended floating gate structure, and an opening corresponding to the movable switch is disposed in the ILD layer to expose the extended floating gate structure. The movable switch includes: a support component and a conductive interconnection component. The support component has one end connecting to the border of conductive interconnection component and another end connecting to the ILD layer, so that the conductive interconnection component can suspend above the opening due to the support component. The conductive interconnection component electrically connects to the extended floating gate structure through the opening when a voltage is applied thereto. Therefore, the write and erase operations may be performed by applying a voltage to the movable switch, which may hinder the conductive interconnection component electrically connected with the floating gate structure. Therefore, charges may be stored into or erased from the floating gate structure to write or erase the memory cell through the extended floating gate structure. Charging or discharging the floating gate structure through a controlling gate structure is no longer need. The floating gate is charged or discharged by utilizing the movable switch which may be controlled by a relatively low voltage (3 V to 6 V). Therefore, high voltages are no longer needed, neither the formation of high voltage devices in the control circuit, which simplifies the structure of the control circuit more simple. In addition, because the erase operation doesn't need high voltages, the device reliability may be increased. Moreover, the power consumption generated by the current in a conventional write operation performed to the floating gate by utilizing hot electrons may be avoided. Further, the write and erase operations are performed directly to the floating gate in the embodiments, thereby significantly reducing the operation period and improving the working efficiency.

### BRIEF DESCRIPTION OF THE DRAWINGS

The above described and other features and advantages will become more apparent to those of ordinary skill in the art by describing in detail exemplary embodiments with reference to the attached drawings. The same reference numbers may be used in different drawings to identify the same or similar elements. The figures are not drawn to scale, and it is noted that the drawings are provided for illustrative purposes only.

FIG. 1 is a schematic cross-sectional view of a conventional stacked-gate memory cell;

FIG. 2 is a schematic structural view illustrating a stacked-gate non-volatile flash memory cell according to an embodiment of the present disclosure;

FIG. 3 is a schematic cross-sectional view illustrating the structure shown in

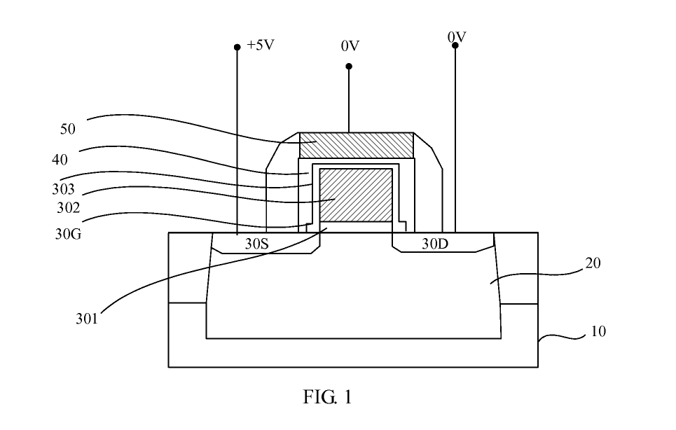

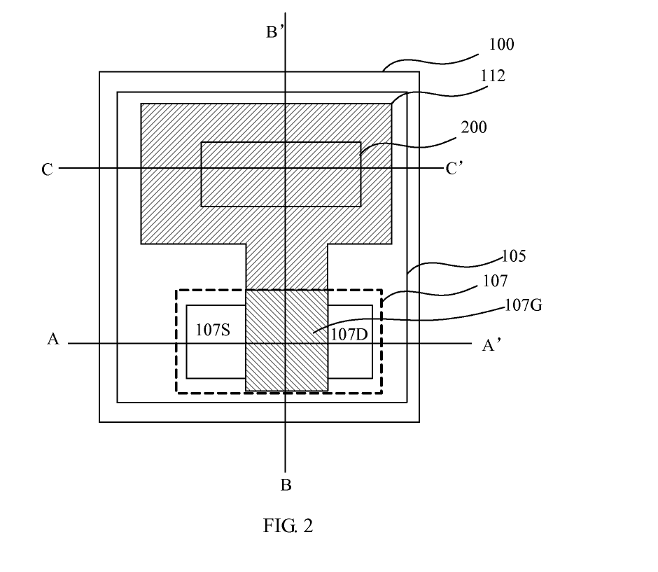

FIG. 2 along A-A′ direction;

FIG. 4 is a schematic cross-sectional view illustrating the structure shown in

FIG. 2 along B-B′ direction;

FIG. 5 is a schematic cross-sectional view illustrating the structure shown in

FIG. 2 along C-C′ direction;

FIG. 6 is a flow chart illustrating a method for forming a stacked-gate non-volatile flash memory cell according to an embodiment of the present disclosure; and

FIGS. 7 to 10 are schematic cross-sectional views of intermediate structures illustrating a method for forming a stacked-gate non-volatile flash memory cell according to an embodiment of the present disclosure.

### DETAILED DESCRIPTION OF THE DISCLOSURE

As described in the background of the present disclosure, the conventional stacked-gate memory cell is erased by applying the mechanism of hot electron tunneling or electron tunneling, in which a high operating voltage is necessarily applied to its controlling gate structure. Normally the operating voltage of an erase operation ranges from about 7 V to about 20 V. Therefore, high-voltage devices are necessary when manufacturing the non-volatile memory devices, resulting in a complicated manufacturing process. Besides, in the conventional stacked-gate memory cell, the hot electron tunneling and electron tunneling occurring in repeated erase operations may lead to the transistor failure. Further, writing and erasing the conventional stacked-gate memory cell needs to open the channel thereof, and hot electrons are generated when a large current passes through the channel, which may increase the power consumption. And the conventional erase operation is realized by applying the electron tunneling effect generated when the gate oxide layer is biased with a high voltage, which leads to a low operating speed.

Erasing or writing a memory cell provided by embodiments of the present disclosure is realized by discharging/charging it with a movable switch thereof. The movable switch is controlled by a relatively low voltage (for example, from about 3 V to about 6 V), so erasing with high voltage may be omitted, which may increase the reliability of the product. No high-voltage devices are necessary in the control circuit, so that the advantages of simple control circuit, low manufacturing cost, high reliability, low power consumption and high efficiency are obtained.

In order to clarify the objects, characteristics and advantages of the disclosure, embodiments of the disclosure will be interpreted in detail in combination with accompanied drawings. Although the present disclosure is disclosed hereinafter with reference to preferred embodiments in detail, it also can be implemented in other different embodiments and those skilled in the art may modify and vary the embodiments without departing from the spirit and scope of the present disclosure. Therefore, the present disclosure should not be limited by the embodiments disclosed herein.

Besides, embodiments of the present disclosure will be illustrated with reference to the accompanying drawings. In the accompanying drawings, for convenience of description, the sizes of respective components may not be drawn based on actual scales. The accompanying drawings are merely examples which should not limit the scope of the present disclosure. Besides, three-dimensional sizes of length, width and depth should be included in real manufacturing.

FIG. 2 is a schematic view illustrating a structure of a stacked-gate non-volatile flash memory cell according to one embodiment of the present disclosure. As shown in FIG. 2, the stacked-gate non-volatile flash memory cell includes a semiconductor structure. The semiconductor structure includes a substrate 100, a doped well 105 in the substrate 100 and a stacked-gate transistor 107 in and on the doped well 105. The stacked-gate transistor 107 includes a source region 107S, a drain region 107D, a floating gate structure 107G between the sour region 107S and the drain region 107D, an isolating layer (not shown in FIG. 2) overlaying the floating gate structure 107G and a controlling gate structure (not shown in FIG. 2) on the isolating layer. The semiconductor structure further includes an extended floating gate structure 112 which is an extended structure of the floating gate structure 107G on the substrate. An interlayer dielectric (ILD) layer is disposed on the semiconductor structure, which is not shown in FIG. 2. The memory cell further includes a movable switch 200 disposed above the extended floating gate structure 112.

Specifically, the substrate 100 may include monocrystalline silicon, polysilicon or amorphous silicon. Or else, the substrate 100 may include silicon, germanium, GaAs, or silicon germanium compound. The substrate 100 may include an epitaxial layer or a silicon-on-insulator structure. The substrate 100 may include other suitable semiconductor materials, which is not illustrated here.

The doped well may be N type or P type. The following description will employ the doped well being N type and the stacked-gate transistor being a PMOS transistor as an example. The N-type well 105 is disposed in the substrate 100. Formation of the N-type well 105 is well known for those skilled in the art. For example, a region of the N-type well is defined on the substrate 100 by applying a lithographic process first; and then, an ion doping process with N type ions like phosphorus ions is performed to form the N-type well.

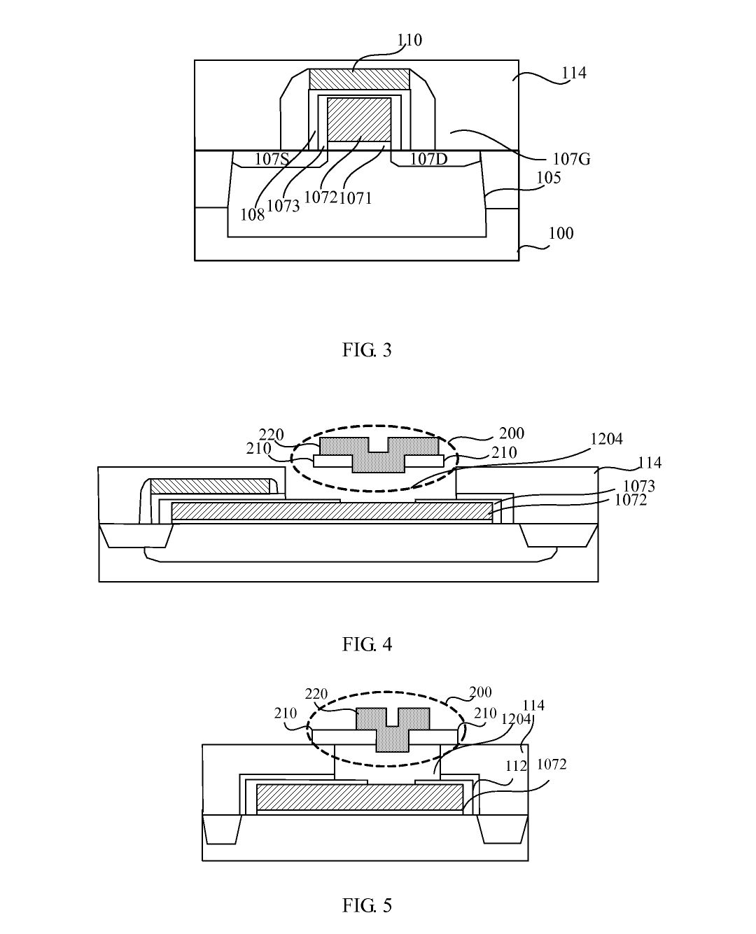

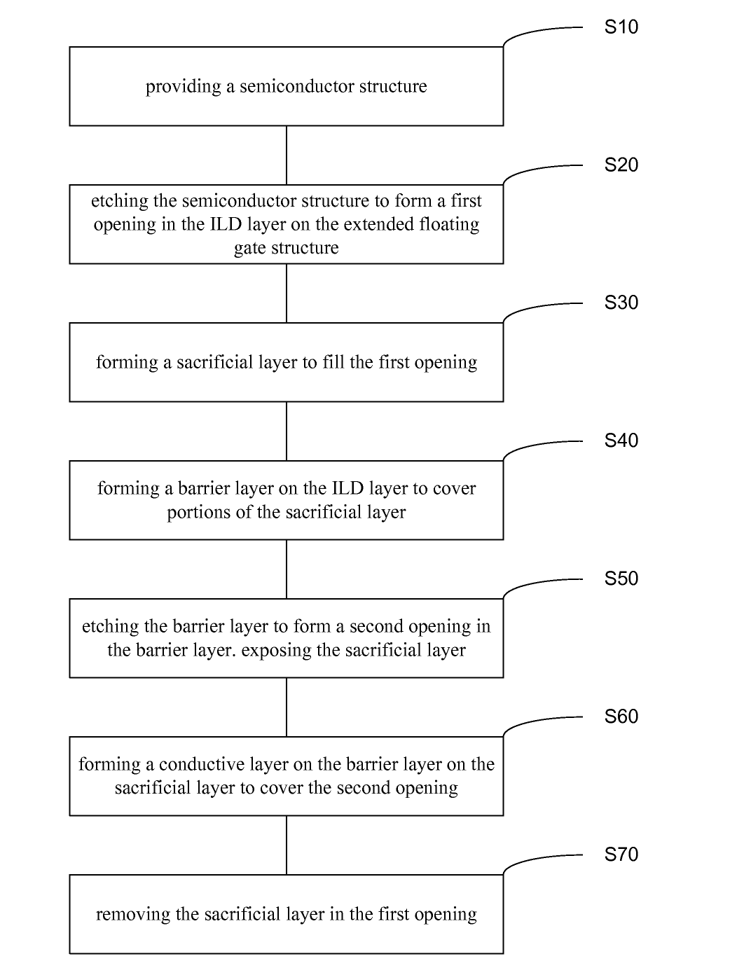

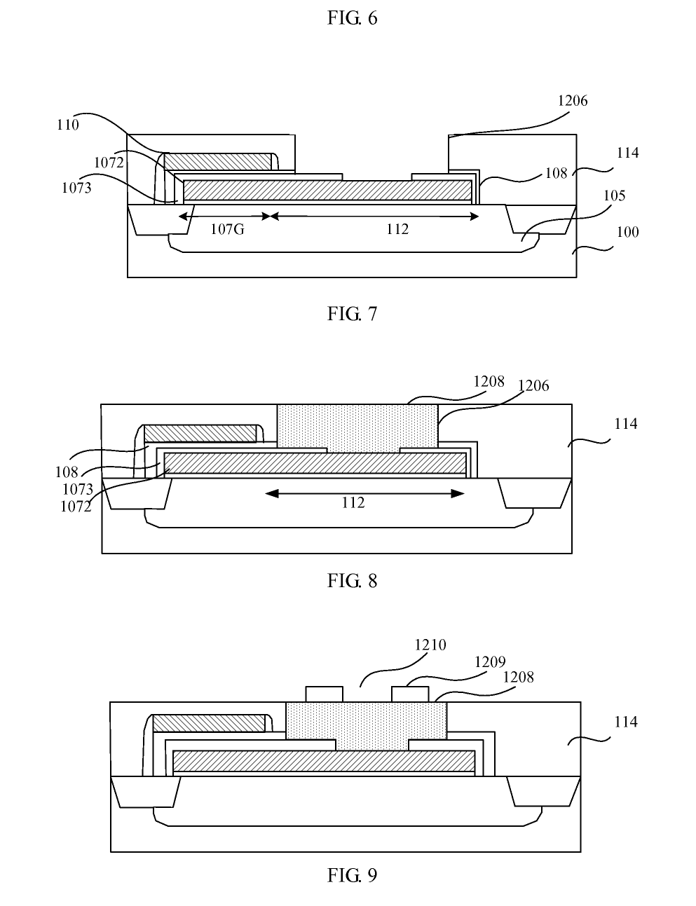

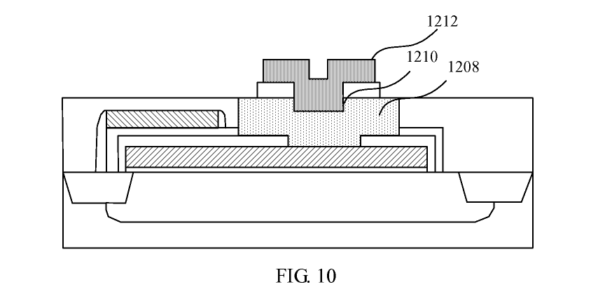

FIG. 3 is a schematic cross-sectional view illustrating the structure shown in FIG. 2 along A-A′ direction. Referring to FIG. 3, the stacked-gate transistor 107 is disposed in and on the N type doped well. The stacked-gate transistor 107 is a PMOS transistor. It could be understood that if the doped well is P type, the stacked-gate transistor 107 may be a NMOS transistor. The stacked-gate transistor 107 includes the source region 107S, the drain region 107D, and the floating gate structure 107G between the source region 107S and the drain region 107D. For example, the floating gate structure 107G may include a gate oxide layer 1071 on the substrate and a polysilicon layer 1072 on the gate oxide layer. The controlling gate structure (which is designated with 110 in FIG. 3) is adapted for performing a read or write operation to the memory cell. The floating gate structure 107G is adapted for data storage. An ILD layer 114 is disposed on the stacked-gate transistor 107 and the extended floating gate structure 112. Other interconnection layers may be disposed on the ILD layer 114 which is adapted for insulating the interconnection layers.

The ILD layer 114 normally includes SiO₂ or doped SiO₂, such as undoped silicon glass (USG), Borophosphosilicate glass (BPSG), borosilicate glass (BSG), phosphosilicate glass (PSG), and the like.

The above described semiconductor structure may include a stacked-gate transistor of a conventional stacked-gate memory cell, which is well known for those skilled in the art and will not be illustrated in detail here.

Optionally, the extended floating gate structure 112 may further include an insulating layer 1073 on the polysilicon layer 1072. As an example, the insulating layer 1073 may include silicon nitride, silicon oxynitride or a stack thereof. The insulating layer 1073 is adapted for protecting the semiconductor structure in regions where metal contacts are not to be formed. Therefore, the metal contacts are only formed in desired regions of the semiconductor structure. The ILD layer 114 overlays the insulating layer 1073. Normally, a portion of the isolating layer (which is designated with 108 in FIG. 3) is disposed on the extended floating gate structure 112.

FIG. 4 is a schematic cross-sectional view illustrating the structure shown in FIG. 2 along B-B′ direction. Referring to FIG. 4, the memory cell further includes the movable switch 200 which is arranged above the extended floating gate structure 112. The extended floating gate structure 112 includes an opening 1204 which exposes the polysilicon layer 1072. The movable switch 200 includes: a support component 210 and a conductive interconnection component 220. The support component 210 has one end connecting to the border of the conductive interconnection component 220, and another end connecting to the ILD layer 114. The conductive interconnection component 220 suspends above the opening 1204 because it is supported by the support component 210. When a voltage is applied to the conductive interconnection component 220, the conductive interconnection component 220 may be forced to enter into the opening 1204 and electrically connect to the polysilicon layer 1072.

In order to force the conductive interconnection component 220 to enter into the opening 1204 and electrically connect to the polysilicon layer 1072 with a relatively low voltage (for example, from about 3 V to about 6 V), the thickness of the ILD layer 114 is optionally selected within a range from about 0.2 μm to about 1 μm.

FIG. 5 is a schematic cross-sectional view illustrating the structure shown in FIG. 2 along C-C′ direction. As an example, the support component 210 includes insulating material and the conductive interconnection component 220 includes metal. The support component 210 may be configured as pins (lead foots) disposed on symmetrical opposite sides of the conductive interconnection component 220, or as an insulating layer such as a silicon nitride layer disposed on the periphery of the conductive interconnection component 220. One end of the support component 210, which connects to the conductive interconnection component 220, is disposed under the conductive interconnection component 220. Another end of the support component 210, which connects to the ILD layer 114, is disposed on the ILD layer 114. Therefore, the conductive interconnection component 220 can suspend above the opening due to the support component 210. When a voltage is applied to the conductive interconnection component 220, the conductive interconnection component 220 and the polysilicon layer 1072 will attract each other due to the electrostatic force. Therefore, the support component 210 bends, and the conductive interconnection component 220 enters the opening 1204, comes into contact and electrically connects to the polysilicon layer 1072. When the conductive interconnection component 220 and the polysilicon layer 1072 are electrically connected, the support component 210 provides rigid support, which increases the mechanical fatigue resistance. The support component 210 may include a material other than silicon nitride, for example, SiO₂, SiON, polysilicon, silicon, or the like.

In order to make the support component 210 bend but not fracture when the conductive interconnection component 220 and the polysilicon layer 1072 are electrically connected, the shape, thickness and width of the support component 120 should be selected by considering the thickness of the conductive interconnection component 220. Optionally, the support component 210 may be configured as one or more strip structures extending across two sides of the conductive interconnection component 220. The support component 210 includes extension portions which are connected with the ILD layer and extended from two sides of the conductive interconnection component 220. The extension portions may be linear pins, meander line pins, or bulk pins distributed all over the periphery of the conductive interconnection component 220. In order to avoid cracking of the support component 210 with the above described structures, the thickness of the support component 120 is selected within a range from about 500 ∈ to about 3000 Å, and the thickness of the conductive interconnection component 220 is selected within a range from about 500 Å to about 5000 Å. Within the above range, it is ensured that the support component may not fracture regardless of the width thereof. However, in practice, the thickness of the support component 210 and the thickness of the conductive interconnection component 220 are selected in consideration of the width of the support component 210.

Optionally, the opening includes a first portion in the ILD layer 114 and a second portion which is corresponding to the central region of the first portion and disposed in the insulating layer. The first portion and the second portion are connected, constituting the opening 1204.

Optionally, the conductive interconnection component 220 includes a convex portion towards the extended floating gate structure 112 corresponding to the position of the opening's second portion. In addition, the conductive interconnection component corresponds to the central region of the opening, i.e., the conductive interconnection component is smaller than the opening, which makes the conductive interconnection component 220 being capable of passing through the opening 1204 without touching the sidewalls of the opening 1204. Therefore, the convex portion of the conductive interconnection component 220 may be electrically connected with the polysilicon layer 1072 exposed by the opening's second portion in the insulating layer. Alternatively, the opening's second portion in the insulating layer may be disposed within the central region of the opening's first portion in the ILD layer, and the position of the convex portion corresponds to the position of the opening's second portion.

In order to establish a nice electrical connection between the conductive interconnection component 220 and the floating gate 1202 when the conductive interconnection component 220 is electrically connected with the polysilicon layer 1072 through the opening 1204, optionally, the convex portion of the conductive interconnection component 220 corresponding to the floating gate structure is configured to have a square cross-section, which has an area ranging from about 0.01 μm² to about 25 μm².

The size of the opening 1204 may be selected according to the size of the conductive interconnection component, ensuring that the conductive interconnection component is spaced at a distance from the opening's sidewalls. For example, the length and width of the opening may be configured as about 1.5 times to about 3 times of the length and width of the conductive interconnection component.

In other embodiments, the extended floating gate structure may not include the insulating layer. Accordingly, only the opening includes only the first portion in the ILD layer.

In other embodiments, the extended floating gate structure may not include the isolating layer. Accordingly, the opening's first portion in the ILD layer can expose the extended floating gate structure.

In the embodiment, the conductive interconnection component suspends above the opening 1204. In a write operation, a positive voltage of 5 V is applied to the conductive interconnection component 220. Due to the electrostatic force, the conductive interconnection component 220 and the polysilicon layer 1072 exposed by the opening will attract and thus electrically connect with each other. Therefore, electrical connection is established and positive charges are stored in the floating gate structure. In an erase operation, a negative voltage of −5 V is applied to the conductive interconnection component 220. Due to the electrostatic force, the conductive interconnection component 220 and the polysilicon layer 1072 exposed by the opening will attract and thus electrically connect with each other. Therefore, electrical connection is established and the positive charges stored in the floating gate are erased.

The movable switch is configured in the memory device according to the embodiments of the present disclosure, so that write and erase operations can be directly performed to the floating gate structure. However, the conventional erase operation is normally performed by applying the mechanism of hot electron tunneling or electron tunneling, in which a high operating voltage is necessary. Normally the operating voltage of a conventional erase operation ranges from about 7 V to about 20 V. Therefore, high-voltage devices are necessarily involved when manufacturing the conventional memory cells, resulting in a complicated manufacturing process. Erasing and writing the memory cell provided by the embodiments of the present disclosure are realized by the movable switch to charge/discharge the memory cell. The movable switch is controlled by a relatively low voltage (for example, from about 3 V to about 6 V), therefore, high-voltage devices may be omitted in the control circuit, which simplifies the control circuit and reduces the manufacturing costs.

Besides, in the conventional stacked-gate memory cell, the hot electron tunneling and electron tunneling occurring in repeated erase operations may lead to the transistor failure. When erasing the memory cell provided by the embodiments of the present disclosure, a high voltage is no longer required, which may improve the reliability of the product. Further, in the embodiment of the present disclosure, the power consumption generated in the conventional write operation which is performed to the floating gate by applying hot electrons may be reduced. In addition, operations are performed directly to the floating-gate in the embodiments, thereby significantly reducing the operation period and improving the working efficiency.

FIG. 6 is a flow chart illustrating a method for forming a stacked-gate non-volatile flash memory cell according to an embodiment of the present disclosure. The method, together with the single-gate non-volatile flash memory cell formed with the method, will be further illustrated with reference to FIG. 6.

The method for forming a stacked-gate non-volatile flash memory cell includes steps as follow.

At step 510, a semiconductor structure is provided.

Specifically, referring to FIG. 7, the semiconductor structure includes a substrate 100, an N type doped well 105 disposed in the substrate 100 and a stacked-gate transistor (not labeled in FIG. 7) disposed in and on the doped well 105. The stacked-gate transistor includes a source region, a drain region, a floating gate structure 107G between the source region and the drain region, an isolating layer 108 overlaying the floating gate structure 107G and a controlling gate structure 110 overlaying the isolating layer 108. The semiconductor structure further includes an extended floating gate structure 112 which is an extended structure of the floating gate structure 107G on the substrate. The extended floating gate structure 112 may include a polysilicon layer 1072 and an insulating layer 1073 on the polysilicon layer. An interlayer dielectric (ILD) layer 114 is disposed on the semiconductor structure.

At step S20, the semiconductor structure is etched to form a first opening in the ILD layer on the extended floating gate structure 110.

Specifically, referring still to FIG. 7, lithographic and etching processes which are well known for those skilled in the art may be applied to form the first opening 1206. For example, a photoresist layer is formed on the semiconductor structure by applying a spin-on process. Thereafter, a pattern in a mask corresponding to the first opening is transferred to the photoresist layer by applying an exposure process. Thereafter, a portion of the photoresist corresponding to the pattern is removed with developer solution, thereby forming a patterned photoresist.

Etching the ILD layer 114 may apply any conventional etching process, such as a chemical etching process or a plasma etching process. In the embodiment, a plasma etching process is applied. The plasma etching process employs one or more selected from CF₄, CHF₃, CH₂F₂, CH₃F, C4F₈ and C₅F₈ as etch gas to etch the ILD layer 114 until the extended floating gate structure 112 is exposed, thus the first opening 1206 is formed.

Normally, a portion of the isolating layer 108 is disposed on the extended floating gate structure 112. The extended floating gate structure 112 may include the polysilicon layer 1072 and the insulating layer 1073 on the polysilicon layer. For example, the insulating layer 1203 may include silicon nitride or silicon oxynitride, which is adapted for protecting the semiconductor structure in regions where metal contacts are not to be formed. Therefore, the metal contacts are formed on the semiconductor structure only in desired regions

Specifically, the step for etching the semiconductor structure to form the first opening in the ILD layer 114 on the extended floating gate structure is performed as follows.

The ILD layer 114 and the isolating layer 108 are etched to form a first portion of the first opening.

Thereafter, a patterned photoresist layer is formed on the extended floating gate structure 112 exposed by the first portion, and a portion of the insulating layer 1073 is exposed by the patterned photoresist layer. Then the insulating layer 1073 exposed by the first opening's first portion is etched, which forms a second portion of the first opening. The first portion in the ILD layer and the second portion in the insulating layer constitute the first opening 1206 which exposes a portion of the polysilicon layer 1072 of the extended floating gate structure 112.

Optionally, the second portion in the insulating layer corresponds to the central region of the first portion in the ILD layer.

At step S30, the first opening is filled to form a sacrificial layer.

Specifically, referring to FIG. 8, a sacrificial layer 1208 may be formed by applying a CVD or spin-on process. For example, a photoresist layer is coated by applying a spin-on process, and the photoresist layer can be taken as the sacrificial layer. The first opening is filled until the top surface of the sacrificial layer 1208 levels with the top surface of the ILD layer 114.

At step S40, a barrier layer is formed on the ILD layer 114, covering portions of the sacrificial layer 1208.

Specifically, referring to FIG. 9, a barrier layer 1209 which may include silicon nitride is formed on the ILD layer 114 by CVD.

In a specific example, the barrier layer covers a portion of the sacrificial layer 1208 corresponding to the central region of the first opening, and a portion of the sacrificial layer 1208 within a region corresponding to the periphery of the first opening is exposed.

At step S50, the barrier layer is etched to form a second opening which exposes a portion of the sacrificial layer.

Specifically, referring still to FIG. 9, a patterned photoresist layer is formed on the barrier layer 1209 and a second opening 1210 is formed by etching the barrier layer with the patterned photoresist layer as a mask. The second opening 1210 exposes a portion of the sacrificial layer. The barrier layer may by etched with an etching process, such as a plasma etching process, which is well known in the art.

Optionally, the position of the second opening corresponds to the position of the first opening's second portion.

At step S60, a conductive layer is formed on the barrier layer. The conductive layer covers the second opening.

Specifically, referring to FIG. 10, a metal layer 1212 is formed by performing a PVD process to fill the second opening 1210 until the metal layer is formed to overlay the second opening 1210. The target in the PVD process may be metal, for example, aluminum. Processing parameters of the PVD process may include: temperature from about 250° C. to about 500° C., chamber pressure from about 10 mTorr to about 18 mTorr, DC power from about 10000 W to about 40000 W, and Ar gas flow rate from about 2 sccm to about 20 sccm.

Further, an etching process may be performed to remove a portion of the conductive layer on the barrier layer, in order that only portions of the conductive layer which are on the periphery of the second opening (i.e., on the barrier layer corresponding to the sacrificial layer)and in the second opening are kept. When forming the conductive layer, the deposition material is likely to fill the second opening preferentially, so the conductive layer may include a convex portion towards the extended floating gate structure, i.e., the convex portion is disposed in the region corresponding to the first opening's second portion in the extended floating gate structure. As a result, in the memory cell formed subsequently, the conductive layer may come into contact with the polysilicon layer through the first opening's second portion in the extended floating gate structure due to electrostatic force, which forms an electrical interconnection.

At step S70, the sacrificial layer in the first opening is removed.

Specifically, referring to FIG. 4, the sacrificial layer may removed by a washing or ashing process. Other than the materials of the sacrificial layer described above, the sacrificial layer may include any suitable material which may be easily removed by the washing or ashing process.

Optionally, the barrier layer and the second opening correspond to the central region of the first opening. The first opening's second portion in the insulating layer corresponds to the central region of the first opening's first portion in the ILD layer. And the convex portion of the conductive layer towards the extended floating gate structure corresponds to the first opening's second portion in the insulating layer.

Optionally, the doped well may be P type and the stacked-gate transistor may be an NMOS transistor.

Further, an embodiment of the present disclosure provides a stacked-gate non-volatile flash memory device including an array of the above described stacked-gate non-volatile flash memory cells.

The disclosure is disclosed, but not limited, by preferred embodiments as above. Based on the disclosure of the disclosure, those skilled in the art can make any variation and modification without departing from the scope of the disclosure. Therefore, any simple modification, variation and polishing based on the embodiments described herein is within the scope of the present disclosure.

What is claimed is:

1. A stacked-gate non-volatile flash memory cell, comprising:
a semiconductor structure, comprising a substrate, a doped well in the substrate, a stacked-gate transistor in and on the doped well, wherein the stacked-gate transistor comprises a source region, a drain region, a floating gate structure disposed between the source and the drain, an isolating layer which covers the floating gate structure and a controlling gate structure disposed on the isolating layer, the semiconductor structure further comprises an extended floating gate structure which is an extended structure of the floating gate structure on the substrate, and an interlayer dielectric layer is disposed on the semiconductor structure; and
a movable switch disposed above the extended floating gate structure, wherein there is an opening corresponding to the movable switch in the ILD layer, and the opening exposes the extended floating gate structure, the movable switch comprises:
a support component and a conductive interconnection component, wherein one end of the support component connects to the border of the conductive interconnection component, another end of the support component connects to the ILD layer, so that the conductive interconnection component suspends above the opening, the conductive interconnection component electrically connects to the extended floating gate structure when a voltage is applied to the conductive interconnection component.

2. The stacked-gate non-volatile flash memory cell according to claim 1, wherein the isolating layer covers the extended floating gate structure, and there is an opening in the isolating layer, the opening in the isolating layer corresponds to the opening in the ILD layer.

3. The stacked-gate non-volatile flash memory cell according to claim 2, wherein the support component comprises insulating material, the support component is configured as pins distributed on two symmetrical opposite sides of the conductive interconnection component, the one end the support component connecting to the conductive interconnection component is disposed under the conductive interconnection component, and the another end of the support component connecting to the ILD layer is disposed on the ILD layer.

4. The stacked-gate non-volatile flash memory cell according to claim 1, wherein the doped well is N type and the stacked-gate transistor is a PMOS transistor.

5. The stacked-gate non-volatile flash memory cell according to claim 1, wherein the doped well is P type and the stacked-gate transistor is an NMOS transistor.

6. The stacked-gate non-volatile flash memory cell according to claim 1, wherein the extended floating gate structure comprises a polysilicon layer and an insulating layer on the polysilicon layer, the opening comprises a first portion in the ILD layer and a second portion which is in the insulating layer and corresponds to the first portion's central region, and the opening's second portion corresponds to the first portion's central region.

7. The stacked-gate non-volatile flash memory cell according to claim 1, wherein the conductive interconnection component comprises a convex portion towards the extended floating gate structure, and the convex portion corresponds to the opening's second portion in the insulating layer.

8. The stacked-gate non-volatile flash memory cell according to claim 1, wherein the conductive interconnection component corresponds to the opening's central region.

9. The stacked-gate non-volatile flash memory cell according to claim 1, wherein the conductive interconnection component comprises metal.

10. A stacked-gate non-volatile flash memory device comprising an array of stacked-gate non-volatile flash memory cells according to claim 1.

11. A method for forming a stacked-gate non-volatile flash memory cell, comprising:
providing a semiconductor structure, wherein the semiconductor structure comprises a substrate, a doped well in the substrate, a stacked-gate transistor in and on the doped well, wherein the stacked-gate transistor comprises a source region, a drain region, a floating gate structure disposed between the source and the drain, an isolating layer which covers the floating gate structure and a controlling gate structure disposed on the isolating layer, the semiconductor structure further comprises an extended floating gate structure which is an extended structure of the floating gate structure on the substrate, and an interlayer dielectric layer is disposed on the semiconductor structure;
etching the semiconductor structure to form a first opening in the ILD layer on the extended floating gate structure;
forming a sacrificial layer to fill the first opening;
forming a barrier layer on the ILD layer, the barrier layer covering portions of the sacrificial layer;
etching the barrier layer to form a second opening in the barrier layer, the second opening exposing the sacrificial layer;
forming a conductive layer on the barrier layer, the conductive layer covering the second opening; and
removing the sacrificial layer in the first opening.

12. The method for forming a stacked-gate non-volatile flash memory cell according to claim 11, wherein the isolating layer covers the extended floating gate structure, the extended floating gate structure comprises a polysilicon layer and an insulating layer disposed on the polysilicon layer, and the step for etching the extended semiconductor structure to form a first opening comprises:
etching the ILD layer and the isolating layer to form a first portion of the first opening; and
etching the insulating layer exposed by the first opening's first portion to form the first opening's second portion in the insulating layer.

13. The method for forming a stacked-gate non-volatile flash memory cell according to claim 12, wherein the barrier layer corresponds to the first opening's central region, and the second opening corresponds to the first opening's central region.

14. The method for forming a stacked-gate non-volatile flash memory cell according to claim 12, wherein the insulating layer comprises silicon nitride.

15. The method for forming a stacked-gate non-volatile flash memory cell according to claim 12, wherein the insulating layer comprises silicon nitride.

16. The method for forming a stacked-gate non-volatile flash memory cell according to claim 12, wherein the conductive layer comprises metal.
